(19) United States
(12) Patent Application Publication
(10) Pub. No.: US 2015/0115209 A1
(43) Pub. Date: Apr. 30, 2015

(54) PHOTOSENSITIVE RESIN COMPOSITION, COLOR FILTER AND LIQUID CRYSTAL DISPLAY DEVICE HAVING THE SAME

(71) Applicant: CHI MEI CORPORATION, Tainan City (TW)

(72) Inventors: Hao-Wei LIAO, KAOHSIUNG CITY (TW); Ching-Yuan TSENG, TAOYUAN COUNTY (TW)

(21) Appl. No.: 14/509,072

(22) Filed: Oct. 8, 2014

(30) Foreign Application Priority Data
Oct. 24, 2013 (TW) 102138501

(51) Int. Cl. G03F 7/038; G02B 5/23; G02B 1/04

(52) U.S. Cl. CPC G03F 7/0384; G02B 1/04; G02B 5/23
USPC 252/586; 430/280.1

(57) ABSTRACT

The present invention relates to a photosensitive resin composition, a color filter and a liquid crystal display device using the same. The photosensitive resin composition includes an alkali-soluble resin (A), a compound having a vinyl unsaturated group (B), a photo initiator (C), a solvent (D) and a black pigment (E) The alkali-soluble resin (A) includes a resin having an unsaturated group (A-1), which is prepared by polymerizing a mixture. The aforementioned compound having a vinyl unsaturated group (B) can include a compound (B-1). The photosensitive resin composition has good reliability at high temperature and high humidity.

### RELATED APPLICATIONS

This application claims priority to Taiwan Application Serial Number 102138501, filed Oct. 24, 2013, which is herein incorporated by reference.

### BACKGROUND

1. Field of Invention

The present invention relates to a photosensitive resin composition for a black matrix, and a color filter and a liquid crystal display devices formed by using the black matrix, more particularly, to provide a photosensitive resin composition for a black matrix with good reliability in an environment of high temperature and high humidity, a color filters and a liquid crystal display devices formed by using the black matrix.

2. Description of Related Art

In recent years, various liquid crystal display (LCD) technologies started to flourish. In order to improve the contrast and display quality of LCD devices, a black matrix is usually disposed among the gaps of the stripes and the dots of a color filter of the LCD device. The black matrix can prevent defects of reduction of the contrast and color purity induced from light leakage among pixels of the LCD device. The conventional materials for the black matrix are mainly vapor deposited films containing chromium, chromium oxide, or the likes. However, when the vapor deposited film is used as the material for the black matrix, there are drawbacks such as complicated process and costly materially. Therefore, to solve this problem, it has been proposed to form the black matrix by using a photosensitive resin composition via photo-lithographic technologies.

The light-shielding requirement of the black matrix in the industry is now getting higher and higher, and one solution for improving the light-shielding of the black matrix is to increase the amount of black pigments. Japanese Patent Publication No. 2006-259716 discloses a photosensitive resin composition used for the black matrix, which contains a high amount of black pigments, an alkali-soluble resin, a photopolymerization initiator, a reactive monomer having a bifunctional group and an organic solvent. The reactive monomer having a bifunctional group can improve the reaction between the compounds, so as to form a highly fine pattern. Therefore, in the photosensitive resin composition, when the light-shielding can be improved by increasing the amount of the black pigments, the sensitivity of the photosensitive resin composition is maintained at the same time.

Furthermore, Japanese Patent Publication No. 2008-268854 discloses a photosensitive resin composition for a black matrix. The photosensitive resin composition includes an alkali-soluble resin having a carboxyl group and an unsaturated group, a photopolymerizable monomer having a vinyl unsaturated group, a photopolymerization initiator and a high amount of black pigments. In the photosensitive resin composition for the black matrix, resolution of the photosensitive resin composition containing high amount of the black matrix can be improved by specific alkali-soluble resin.

In present technology, although the light-shielding can improve via increase the amount of the black pigment, the above-mentioned prior photosensitive resin compositions tend to have a defect of poor reliability in an environment of high temperature and high humidity after development. According to the above, there is still a need to develop a photosensitive resin composition for the black matrix with good reliability under high temperature and high humidity conditions.

### SUMMARY

Accordingly, one aspect of the present invention is to provide a photosensitive resin composition, and this photosensitive resin composition has good reliability in high temperature and high humidity environment,

Another aspect of the present invention is to provide a black matrix, which is produced by using the above-mentioned photosensitive resin composition.

Another aspect of the present invention is to provide a color filter, which contains the above-mentioned black matrix.

A further aspect of the present invention is to provide a liquid crystal display device, which contains the aforementioned color filter.

According to the above-mentioned aspects of the present invention, a photosensitive resin composition is proposed. The photosensitive resin composition contains an alkali-soluble resin (A), a compound having a vinyl unsaturated group (B), a photo initiator (C), a solvent (D) and a black pigment (E), details will be described below.

### Photosensitive Resin Composition Alkali-Soluble Resin (a)

The alkali-soluble resin (A) of the present invention may include a resin having an unsaturated group (A-1). The resin having an unsaturated group (A-1) is prepared by polymerizing of a mixture, the mixture includes an epoxy compound having at least two epoxy groups (i) and a compound having at least one carboxyl group and at least one vinyl unsaturated group (ii). Preferably, the mixture can selectively include a carboxylic anhydride compound (iii) and/or a compound having an epoxy group (iv).

### Epoxy Compound Having At Least Two Epoxy Groups (I)

The above-mentioned epoxy compound having at least two epoxy groups (i) may have a structure of formula (II) or formula (III):

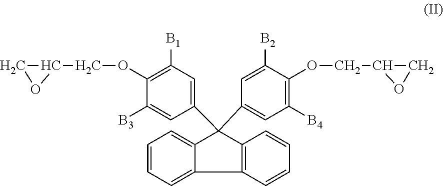

in formula (II), B₁, B₂, B₃ and B₄ are independently the same or different, and B₁, B₂, B₃ and B₄ independently represent a hydrogen atom, a halogen atom, an alkyl group of 1 to 5 carbons, an alkoxy group of 1 to 5 carbons, an aryl group of 1 to 12 carbons or an aralkyl group of 6 to 12 carbons.

The epoxy compound having at least two epoxy groups (i) having a structure of formula (II) can include but is not limited to a bisphenol fluorene having epoxy groups, which is obtained by reacting with bisphenol fluorene and epihalohydrin.

For examples, the above-mentioned bisphenol fluorene can include but is not limited to 9,9-bis(4-hydroxyphenyl)fluorene,
9,9-bis(4-hydroxy-3-methylphenyl)fluorene,
9,9-bis(4-hydroxy-3-chlorophenyl)fluorene,
9,9-bis(4-hydroxy-3-bromophenyl)fluorene,
9,9-bis(4-hydroxy-3-fluorophenyl)fluorene,
9,9-bis(4-hydroxy-3-methoxyphenyl)fluorene,
9,9-bis(4-hydroxy-3,5-dimethylphenyl)fluorene,
9,9-bis(4-hydroxy-3,5-dichlorophenyl)fluorene,
9,9-bis(4-hydroxy-3,5-dibromophenyl)fluorene, and the like.

The above-mentioned epihalohydrin may include but is not limited to epichlorohydrin, epibromohydrin or the like.

The above-mentioned bisphenol fluorine having epoxy groups which is obtained by reacting bisphenol fluorene with epihalohydrin may include but is not limited to commercially products, manufactured by Nippon Steel Chemical Co. Ltd., and the trade names are ESP-300 or the like, products manufactured by Osaka Gas Co. Ltd. and the trade names are PG-100, EG-210 or the like, products manufactured by S.M.S. Technology Co. Ltd., and the trade names are SMS-F9PhPG SMS-F9CrG SMS-F914PG or the like.

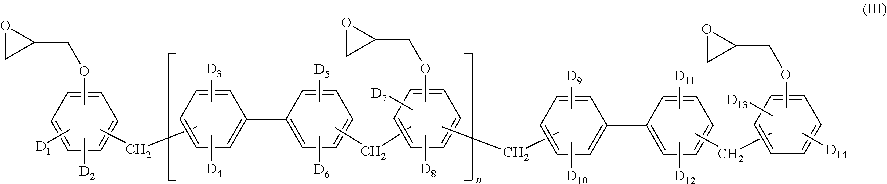

In formula (III), D₁ to D₁₄ can be independently the same or different, and D₁ to D₁₄ may independently represent a hydrogen atom, a halogen atom, an alkyl group of 1 to 8 carbons, an aryl group of 6 to 15 carbons, and n represents an integer from 0 to 10.

Preferably, the epoxy compound having at least two epoxy groups (i) having a structure of formula (III) is obtained by synthesizing a compound with the structure shown in formula (IV) and epihalohydrin to a reaction in the presence of alkali metal hydroxides:

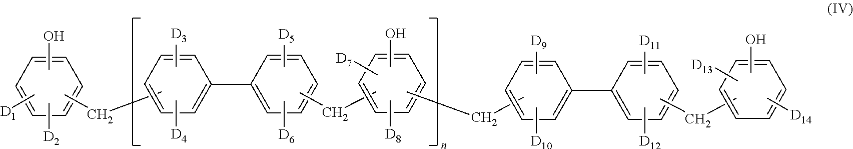

in formula (IV), D₁ to D₁₄ and n is the same as above, therefore not repeated here.

Preferably, in the present of an acid catalyst, after the compound having a structure of formula (V) is reacted with phenol compounds by a condensation reaction, the aforementioned compound having a structure of formula (IV) is obtained. And then, an excess amount of the epihalohydrin are added to subject to a dehydrohalogenation reaction, so as to obtain the epoxy compound having at least two epoxy groups (i) having a structure of formula (III):

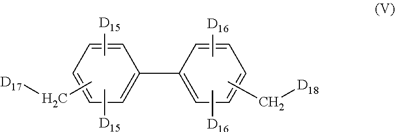

in formula (V), D₁₅ to D₁₆ can be the same or different, and D₁₅ to D₁₆ independently represent a hydrogen atom, a halogen, an alkyl group of 1 to 8 carbons, an aryl group of 6 to 15 carbons; D₁₇ and D₁₈ can be the same or different, and D₁₇ and D₁₈ independently represent a halogen, an alkyl group of 1 to 6 carbons or an alkoxy group of 1 to 6 carbons. The halogen atom represents chlorine or bromine. The alkyl group represents methyl group, ethyl group, or t-butyl group. The alkoxy group represents methoxy group or ethoxy group.

The above-mentioned phenol compounds can include but is not limited to, phenol, cresol, ethylphenol, n-propylphenol, isobutylphenol, t-butylphenol, octylphenol, nonylphenol, xylenol, methylbutylphenol, di-t-butylphenol, vinylphenol, propenylphenol, ethynylphenol, cyclopentylphenol, cyclohexylpheriol, cyclohexyicresol and the like. The aforesaid phenol compounds can be used alone or in a combination thereof.

Based on the compound having a structure of formula (V) as 1 mole, an amount of phenol compounds is 0.5 to 20 moles, and preferably is 2 to 15 moles.

The above-mentioned acid catalyst may include but is not limited to hydrochloric acid, sulfuric acid, p-toluenesulfonic acid, oxalic acid, boron trifluoride, aluminium chloride anhydrous, zinc chloride and the like. The aforesaid acid catalyst can be used alone or in a combination thereof. Preferably, the acid catalyst is selected from p-toluenesulfonic acid, sulfuric acid or hydrochloric acid.

There is no specific limitation to the amount of the acid catalyst. Based on the compound having a structure of formula (V) as 100 wt %, the amount of the acid catalyst preferably is 0.1 wt % to 30 wt %.

The above-mentioned condensation reaction can be performed in the absence of solvents or in the presence of organic solvents. The organic solvents may include but is not limited to toluene, xylene, methyl isobutyl ketone and the like. The aforesaid organic solvents can be used alone or in a combination thereof.

Based on the compound having a structure of formula (V) as 100 wt %, the amount of the organic solvent preferably is 50 wt % to 300 wt %, and more preferably is 100 wt % to 250 wt %. Preferably, the condensation reaction is performed at 40° C. to 180° C., and the reaction time is 1 hour to 8 hours.

After the aforesaid condensation reaction is complete, neutralization or rinsing treatment can be performed. The neutralization treatment is to adjust the pH value of the solution to 3 to 7, and preferably is 5 to 7. The rinsing treatment is performed with a neutralizing agent, and the neutralizing agent is a basic compound, which includes but is not limited to alkali metal hydroxides such as sodium hydroxide, potassium hydroxide and the like; alkaline earth metal hydroxides such as calcium hydroxide, magnesium hydroxide and the like; organic amines such as diethylene triamine, triethylene tetramine, aniline, phenylene diamine and the like; or ammonia, sodium dihydrogen phosphate and other compounds. The above-mentioned rinsing treatment can be performed in a commonly used manner. For example, the solution after the reaction is repeatedly extracted by adding an aqueous solution containing the neutralizing agent. After the neutralization or rinsing treatment is complete, the unreacted phenols and solvents can be removed via distillation at a reduced pressure, and then concentrated to obtain the compound having a structure of formula (IV).

The above-mentioned epihalohydrin may include but is not limited to 3-chloro-1,2-epoxypropane, 3-bromo-1,2-epoxypropane or a combination thereof. Before the above-mentioned dehydrohalogenation reaction is performed, alkaline metal hydroxides such as sodium hydroxide, potassium hydroxide and the like can be added prior to or during the dehydrohalogenation reaction. The above-mentioned dehydrohalogenation is performed at 20° C. to 120° C. for 1 hour to 10 hours.

The above-mentioned alkaline metal hydroxides added in the dehydrohalogenation reaction can be an aqueous solution. In this embodiment, when the above-mentioned alkaline metal hydroxide aqueous solution is continuously added to a dehydrohalogenation reaction system, the water and epihalohydrin can be continuously distilled at atmospheric pressure or at a reduced pressure, thereby separating and removing the water, and the epihalohydrin can be continuously refluxed into the reaction system at the same time.

Before the above-mentioned dehydrohalogenation reaction is performed, quaternary ammonium salts, such as tetramethyl ammonium chloride, tetramethyl ammonium bromide, trimethyl benzyl ammonium chloride and the like can be added as a catalyst, and reacting at 50° C. to 150° C. for 1 hour to 5 hours. Then, alkaline metal hydroxide or an aqueous solution thereof is added, and the dehydrohalogenation reaction is performed at 20° C. to 120° C. for 1 hour to 10 hours.

Based on the total equivalent hydroxyl groups in the compound having a structure of formula (IV) as 1 equivalent, the amount of the above-mentioned epihalohydrin is 1 equivalent to 20 equivalents, and preferably is 2 equivalents to 10 equivalents. Based on the total equivalent hydroxyl groups in the compound with the structure in formula (IV) as equivalent, an amount of the above-mentioned alkaline metal hydroxide that was added to the dehydrohalogenation reaction is 0.8 equivalent to 15 equivalents, and preferably is 0.9 equivalent to 11 equivalents.

In addition, to carry out the above-mentioned dehydrohalogenation reaction smoothly, besides adding alcohols such as methanol, ethanol and the like, polar aprotic solvents such as dimethyl sulfone, dimethyl sulfoxide and the like can also be added to perform the reaction. When the alcohol is used, based on the epihalohydrin as 100 wt %, the amount of alcohol can be 2 wt % to 20 wt %, and preferably is 4 wt % to 15 wt %. When the polar aprotic solvent is used, based on the epihalohydrin as 100 wt %, the amount of polar aprotic solvent can be 5 wt % to 100 wt %, and preferably is 10 wt % to 90 wt %.

After the dehydrohalogenation reaction is complete, a rinse treatment can be optionally performed. Afterwards, the epihalohydrin, the alcohol, the polar aprotic solvent and the like are removed by heating at reduced pressure. The above-mentioned heating at reduced pressure can be performed at 110° C. to 250° C. and a pressure less than 1.3 kPa (10 mmHg).

To prevent the resulting epoxy resin from containing hydrolysable halogens, solvents such as toluene, methyl isobutyl ketone or the like, and alkali metal hydroxide solutions such as sodium hydroxide, potassium hydroxide or the like can be added to the solution after the dehydrohalogenation reaction to perform the dehydrohalogenation reaction again. During the dehydrohalogenation reaction, based on the total equivalent of hydroxyl groups in the compound having a structure of formula (IV) as 1 equivalent, the amount of alkali metal hydroxide is 0.01 moles to 0.3 moles, and preferably is 0.05 moles to 0.2 moles. In addition, the above-mentioned dehydrohalogenation reaction is performed at 50° C. to 120° C. for 0.5 hour to 2 hours.

After the dehydrohalogenation reaction is complete, salts can be removed by performing filtration step, rinse step and the like. In addition, solvents such as toluene, methyl isobutyl ketone or the like can be removed by heating at reduced pressure, thereby obtaining an epoxy compound having at least two epoxy groups (i) having a structure of formula (III). The above-mentioned epoxy compound having at least two epoxy groups (i) having a structure of formula (III) can include but is not limited to commercially available products manufactured by Nippon Kayaku Co. Ltd., and the trade names are NC-3000, NC-3000H, NC-3000S, NC-3000P and the like.

### Compound Having at Least One Carboxyl Group and at Least One Vinyl Unsaturated Group (II)

The aforementioned compound having at least one carboxyl group and at least one vinyl unsaturated group (ii) is selected from the group consisting of the following subgroups (1) to (3): (1) acrylic acid, methacrylic acid, 2-methacryloyloxyethyl butanedioic acid, 2-methacryloyloxybutyl butanedioic acid, 2-methacryloyloxyethyl hexanedioic acid, 2-methacryloyloxybutyl hexanedioic acid, 2-methacryloyloxyethyl hexahydrophthalic acid, 2-methacryloyloxyethyl maleic acid, 2-methacryloyloxypropy maleic acid, 2-methacryloyloxybutyl maleic acid, 2-methacryloyloxypropyl butanedioic acid, 2-methacryloyloxypropyl hexanedioic acid, 2-methacryloyloxypropyl tetrahydrophthalic acid, 2-methacryloyloxypropyl hydrophthalic acid, 2-methacryloyloxybutyl hydrophthalic acid or 2-methacryloyloxybutyl hydrophthalic acid; (2) a compound obtained by reacting (methyl)acrylate esters having hydroxyl group(s) with a dicarboxylic acid compound, wherein the dicarboxylic acid compound may include, but not limited to, hexanedioic acid, butanedioic acid, maleic acid, and phthalic acid; (3) a hemiester compound obtained by reacting (methyl)acrylate ester having hydroxyl group(s) with a carboxylic acid anhydride compound (iii).

The above-mentioned (methyl)acrylate esters having hydroxyl group(s) may include but is not limited to (2-hydroxyethyl)acrylate, (2-hydroxyethyl)methacrylate, (2-hydroxypropyl)acrylate, (2-hydroxypropyl)methacrylate, (4-hydroxybutyl)acrylate, (4-hydroxybutyl)methacrylate, pentaerythritol triacrylate and the like.

The above-mentioned carboxylic acid anhydride compounds can be the same as the aforementioned carboxylic anhydride compound (iii) in the resin having an unsaturated group (A-1), therefore not repeated here.

Carboxylic Anhydride Compound (iii)

The above-mentioned carboxylic anhydride compound (iii) can be selected from the group consisting of the following subgroups (1) to (2): (1) dicarboxylic acid anhydride compounds such as butanedioic anhydride, maleic anhydride, itaconic anhydride, phthalic anhydride, tetrahydrophthalic anhydride, hexahydrophthaiic anhydride, methyltetrahydrophthalic anhydride, methylhexahydrophthalic anhydride, methyl endo-methylene tetrahydrophthalic anhydride, chlorendic anhydride, 1,3-dioxoisobenzofuran-5-carboxylic anhydride and the like; and (2) tetracarboxylic acid anhydride compounds such as benzophenone tetracarboxylic dianhydride (BTDA), diphenyl tetracarboxylic dianhydride, diphenyl ether tetracarboxylic acid dianhydride and the like.

### Compound Having an Epoxy Group (iv)

The above-mentioned compound having an epoxy group (iv) can be selected from the group consisting of glycidyl methacrylate, 3,4-epoxycyclohexyl methacrylate, glycidyl ether compounds having unsaturated group(s), unsaturated compounds having epoxy group(s) or a combination thereof. The aforementioned glycidyl ether compounds having unsaturated group(s) may include, but not limited to, commercially available products such as Denacol EX-111, Denacol EX-121, Denacol EX-141, Denacol EX-145, Denacol EX-146, Denacol EX-171, Denacol EX-192 and the like manufactured by Nagase ChemteX Corporation.

The above-mentioned resin having an unsaturated group (A-1) can be obtained by polymerization of the epoxy compound having at least two epoxy groups (i) having a structure of formula (II) with the compound having at least one carboxyl group and at least one vinyl unsaturated group (ii) to form a reacting product having hydroxyl group(s) and than reacting the reaction product with the carboxylic anhydride compound (iii). Based on the total equivalent hydroxyl groups of the reacting product having hydroxyl group(s) as 1 equivalent, the equivalent anhydride groups in the carboxylic anhydride compound (iii) is preferably 0.4 to 1 equivalent, and more preferably is 0.75 to 1 equivalent. When a plurality of the carboxylic anhydride compound (iii) is applied, it can be added sequentially or simultaneously into the reaction. When a dicarboxylic acid anhydride compound and tetracarboxylic acid anhydride compound is used as the carboxylic anhydride compound (iii), the molar ratio of the dicarboxylic acid anhydride compound and the tetracarboxylic acid anhydride compound is preferably 1:99 to 90:10, and more preferably is 5:95 to 80:20. In addition, the above-mentioned reaction can be performed at a 50° C. to 130° C.

The above-mentioned resin having an unsaturated group (A-1) can be obtained by reacting the epoxy compound having at least two epoxy groups (i) of formula (III) with the compound having at least one carboxyl group and at least one vinyl unsaturated group (ii) to form an reacting product having hydroxyl group(s), and then the reacting product is subjected to a polymerization reaction by adding the carboxylic anhydride compound (iii) and/or the compound having an epoxy group (iv). Based on the total equivalent epoxy groups of the epoxy compound having at least two epoxy groups (i) of formula (III) as 1 equivalent, the acid value equivalent of the above-mentioned compound having at least one carboxyl group and at least one vinyl unsaturated group (ii) is preferably 0.8 equivalent to 1.5 equivalent, and more preferably is 0.9 equivalent to 1.1 equivalent. Based on the hydroxyl groups in the above-mentioned reacting product having hydroxyl group(s) as 100 mole %, the amount of the anhydride compound (iii) is 10 mole % to 100 mole %, preferably is 20 mole % to 100 mole %, and more preferably is 30 mole % to 100 mole %.

When the above-mentioned resin having an unsaturated group (A-1) is prepared, alkaline compounds are usually added to the reacting solution as a reacting catalyst to accelerate the reaction. The above-mentioned reacting catalyst may include but is not limited to triphenyl phosphine, triphenyl stibine, triethylamine, triethanolamine, tetramethylam onium chloride, benzyltriethylammonium chloride and the like. The above-mentioned reacting catalyst may be used alone or in a combination of two or more.

Based on the total amount of the epoxy compound having at least two epoxy groups (i) and the compound having at least one carboxyl group and at least one vinyl unsaturated group (ii) as 100 parts by weight, the amount of the reacting catalyst is preferably 0.01 parts by weight to 10 parts by weight, and more preferably is 0.3 parts by weight to 5 parts by weight.

In addition, to control the degree of polymerization, a polymerization inhibitor is usually added into the reacting solution. The aforementioned polymerization inhibitor may include but is not limited to methoxyphenol, methylhydroquinone, hydroquinone, 2,6-di-t-butyl-p-cresol, phenothiazine and the like. The above-mentioned polymerization inhibitor may be used alone or in a combination of two or more. Based on the total amount of the epoxy compound having at least two epoxy groups (i) and the compound having at least one carboxyl group and at least one vinyl unsaturated group (ii) as 100 parts by weight, the amount of the polymerization inhibitor is preferably 0.01 parts by weight to 10 parts by weight, and more preferably is 0.1 parts by weight to 5 parts by weight.

When the resin having an unsaturated group (A-1) is prepared, a polymerization solvent can be used if necessary. Specific examples of the above-mentioned polymerization solvent are alcohol compounds such as ethanol, propanol, isopropanol, butanol, isobutanol, 2-butanol, hexanol, ethylene glycol or the like; ketone compounds such as methyl ethyl ketone, cyclohexanone or the like; aromatic hydrocarbon compounds such as toluene, xylene or the like; cellosolve compounds such as cellosolve, butyl cellosolve or the like; carbitol compounds such as carbitol, butyl carbitol or the like; propylene glycol alkyl ether compounds such as propylene glycol monomethyl ether or the like; poly(propylene glycol)alkyl ether compounds such as di(propylene glycol)methyl ether or the like; acetate ester compounds such as ethyl acetate, butyl acetate, ethylene glycol monoethyl ether acetate, propylene glycol methyl ether acetate or the like; alkyl lactate compounds such as ethyl lactate, butyl lactate or the like; or dialkyl glycol ether compounds. The aforementioned polymerization solvent may be used alone or in a combination of two or more. Furthermore, the acid value of the resin having an unsaturated group (A-1) is preferably 50 mgKOH/g to 200 mgKOH/g and more preferably is 60 mgKOH/g to 150 mgkOH/g.

Based on the alkali-soluble resin (A) as 100 parts by weight, the amount of the aforementioned resin having an unsaturated group (A-1) is 30 parts by weight to 100 parts by weight, preferably is 50 parts by weight to 100 parts by weight, and more preferably is 70 parts by weight to 100 parts by weight. If the alkali-soluble resin (A) of the photosensitive resin composition does not contain the resin having an unsaturated group (A-1), the photosensitive resin composition product will have poor reliability in an environment of high temperature and high humidity.

### Other Alkali-Soluble Resins (A-2)

The alkali-soluble resin (A) may optionally include an other alkali-soluble resins (A-2). The other alkali-soluble resins (A-2) may include but is not limited to resins containing carboxylic or hydroxyl groups. The other alkali-soluble resins (A-2) may include but is not limited to acrylic resins besides the resin having an unsaturated group (A-1), urethane resins, novolac resins and the like.

Based on the alkali-soluble resins (A) as 100 parts by weight, an amount of the other alkali-soluble resins (A-2) is preferably 0 to 70 parts by weight, more preferably is 0 to 50 parts by weight, and further more preferably is 0 to 30 parts by weight.

### Compound Having a Vinyl Unsaturated Group (B)

The compound having a vinyl unsaturated group (B) of the present invention may include a compound (B-1) having a structure of formula (1).

### Compound (B) Having a Structure of Formula (I)

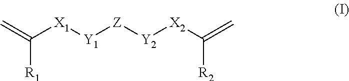

In formula (I), R₁ and R₂ are independently the same or different, and R₁ and R₂ independently represent a hydrogen atom or a methyl group; X₁ and X₂ are independently the same or different, and X₁ and X₂ independently represent a single bond, an ether group (having a structure of —O—), oxyalkylene or ester group [having a structure of —C(O)O— or —OC(O)—]; Y₁ and Y₂ are independently the same or different, and Y₁ and Y₂ independently represent a single bond, a methylene group (having a structure of —CH₂—), a ethylene group (having a structure of —CH₂CH₂—) an ethyleneoxy group (having a structure of —C₂H₄O— or —OC₂H₄—), a propyleneoxy group (having a structure of —C₃H₆O— or —OC₃H₆—), a polyethyleneoxy group or a polypropyleneoxy group; Z represents a group having a structure of formula (I-1), formula (I-2a) or formula (I-2b), or a group combination of two or more of formula (I-2a) and formula (I-2b):

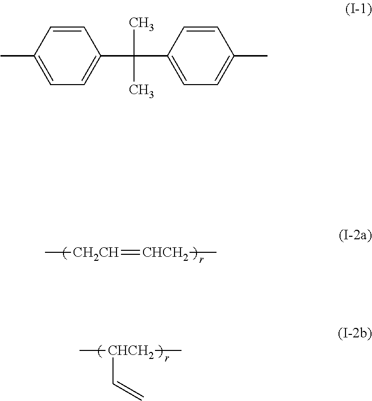

in formula (I-1), formula (I-2a) and formula (I-2b), the r can represent an integer greater than 1.

Preferably, both the aforementioned R₁ and R₂ represent a hydrogen atom.

The above-mentioned X₁ and X₂ can preferably represent an ester group.

The aforementioned structure shown in formula (I-1) contains a bisphenol A group in which two hydroxyl group has been removed, and formula (I-2a) and formula (I-2b) contains a polybutadiene group.

The aforementioned r represents an integer greater than 1. The upper limit of r is 200, and r preferably is 100.

In the compound (B-1) having a structure of formula (I), the groups represented by Z having a structure of formula (I-1), formula (I-2a) and formula (I-2b) contains a carbon-carbon double bond structure, and molecular ends of the compound (B-1) contain alkenyl groups.

Preferably, the compound (B-1) having a structure of formula (I) can be a diacrylate compound. Both the R₁ and R₂ represent a hydrogen atom, and X₁ and X₂ represent an ester group.

To obtain a more rigid film, the above-mentioned Z can preferably represent the organic groups having a structure of formula (I-1). To obtain a more flexible film, the above-mentioned Z can preferably represent the organic groups combination of two or more of the structures shown in formula (I-2a) and formula (I-2b).

In the compound (B-1) having a structure of formula (I), when the Z represents the organic groups having a structure of formula (I-1), the Y₁ and Y₂ bonded with Z preferably represent a polyethyleneoxy group bonded with an ether group. The number of repeating units of the ethyleneoxy group in the polyethyleneoxy group is not particularly limited, and preferably is 1 to 30.

Preferably, the compound (B-1) having a structure of formula (I) is a compound having a structure of formula (I-3). The compound having a structure of formula (I-3) contains a bisphenol group and a polyethyleneoxy group, and two end groups contain an acrylic acid group:

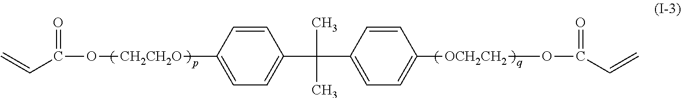

in formula (I-3), the p and the q independently represent an integer greater than 1, and p+q is 1 to 30.

The above-mentioned compound having a bisphenol group shown in formula (I-3) may include but is not limited to NK Ester A-BPE-10, A-BPE-4 or the like manufactured by Shin-Nakamura Chemical Co. Ltd.; SR349, SR601 and the like manufactured by Sartomer Company Inc.: BLEMMER ADPE-150 manufactured by NOF corporation; ARONIX M-210 and M-211B and the like manufactured by Toagosei Co. Ltd.; Light Acrylate BP-4EA and the like manufactured by Kyoeisha Chemical Industry Co. Ltd.; BPE-4 manufactured by Daichi Kogyo Seiyaku Co. Ltd.; Viscoat#700 manufactured by Osaka Organic Chemical Industry Co. Ltd,; Ebecryl 150, Ebecryl 1150 and the like manufactured by Daicel-UCB Ltd.

In the above-mentioned compound (B-1) shown in formula (I), Z may represent the group having a structure of formula (I-2a) formula (I-2b) or a combination thereof. The compound (B-1) is preferably an oligomer, and the number of repeating units is 5 to 100.

The aforementioned oligomer is preferably an oligomer with an average molecular weight of 400 to 10000, and preferably is 500 to 5000.

The aforementioned compound (B-1) shown in formula (I) may be a compound having a polybutadiene group. Z may represent the groups shown in formula (I-2a), formula (I-2b) or a combination of formula (I-2a) and formula (I-2b). Y₁ and Y₂ is preferably a methylene group.

The aforementioned compound having a diacrylate group and polybutadiene group may include but is not limited to CN301, CN303, CN307 and the like manufactured by Sartomer Co. Inc.; EMA-3000 manufactured by Nippon Soda Co. Ltd.

The compound (B-1) shown in formula (I) can be used alone or in a combination of two or more.

Based on the alkali-soluble resins (A) of the photosensitive resin composition as 100 parts by weight, the amount of the compound (B-1) shown in formula (I) is 1 part by weight to 15 parts by weight, preferably is 1.5 parts by weight to 12 parts by weight, and more preferably is 2 parts by weight to 10 parts by weight.

Since the compound (B-1) shown in formula (I) of the compound having a vinyl unsaturated group (B) can react with the resin having an unsaturated group (A-1), so as to form a denser reticular solid, thereby preventing the reticular solid from water vapor infiltration. On the contrary, when the compound having a vinyl unsaturated group (B) does not use the aforementioned compound (B-1) shown in formula (I), the photosensitive resin composition product has defects of poor reliability in a environment of high temperature and high humidity.

### Other Compounds Having a Vinyl Unsaturated Group (B-2)

The compound having a vinyl unsaturated group (B) may selectively include other compounds having a vinyl unsaturated group (B-2). The other compounds having a vinyl unsaturated group (B-2) can be selected from compounds having one vinyl unsaturated group or compounds having two or more (including two) vinyl unsaturated groups.

The above-mentioned compounds having one vinyl unsaturated group can include but is not limited to (meth)acrylamide, (meth)acryloylmorpholine, 7-amine-3,7-dimethyloctyl(meth)acrylate, isobutoxymethyl(meth)acryfamide, isobornyloxyethyl(meth)acrylate, isobornyl(meth)acrylate, 2-ethylhexyl(meth)acrylate, ethyldiethylene glycol(meth)acrylate, t-octyl(meth)acrylamide, diacetone(meth)acrylamide, dimethylaminoethyl(meth)acrylate, dodecyl(meth)acrylate, dicyclopentenyloxyethyl(meth)acrylate, dicyciopentadiene(meth)acrylate, N,N-dimethyl(meth)acrylamide, tetrachlorophenyl(meth)acrylate, 2-tetrachlorophenoxyethyl(meth)acrylate, tetrahyclrofurfuryl(meth)acrylate, tetrabromoethyl(meth)acrylate, 2-tetrabromophenoxyethyl(meth)acrylate, 2-trichlorophenoxyethyl(meth)acrylate, tribromophenyl(meth)acrylate, 2-tribromophenoxyethyl(meth)acrylate, 2-hydroxyethyl(meth)acrylate, 2-hydroxypropyl(meth)acrylate, vinylcaprolactam, N-vinylpyrrolidone, phenoxyethyl(meth)acrylate, pentachlorophenyl(meth)acrylate, pentabromophenyl(meth)acrylate, polyethylene glycol mono(meth)acrylate, polypropylene glycol mono(meth)acrylate, bornyl(meth)acrylate, or the like. The aforementioned compounds having one vinyl unsaturated group can be used alone or in a combination of two or more.

The above-mentioned compounds having two or more (including two) vinyl unsaturated groups can include but is not limited to ethylene glycol di(meth)acrylate, dicyclopentenyl di(meth)acrylate, triethylene glycol di(meth)acrylate, tetraethylene glycol di(meth)acrylate, tris(2-hydroxyethyl)isocyanurate di(meth)acrylate, tris(2-hydroxyethyl)isocyanurate tri(meth)acrylate, caprolactone-modified tris(2-hydroxyethyl)isocyanurate tri(meth)acrylate, trimethylolpropyl tri(meth)acrylate, EO-modified trimethylolpropy tri(meth)acrylate, PO-modified trimethylolpropyl tri(meth)acrylate, tripropylene glycol di(meth)acrylate, neopentyl glycol di(meth)acrylate, 1,4-butanediol di(meth)acrylate, 1,6-hexanediol di(meth)acrylate, pentaerythritol tri(meth)acrylate, pentaerythritol tetra(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, caprolactone-modified dipentaerythritol hexa(meth)acrylate, caprolactone-modified dipentaerythritol penta(meth)acrylate, di(trimethylolpropane) tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, PO-modified glycerol tri(meth)acrylate, EO-modified bisphenol F di(meth)acrylate, novolac polyglycidyl ether(meth)acrylate, or the like. The above-mentioned compounds having two or more (including two) vinyl unsaturated groups can be used alone or in a combination of two or more.

Specific examples of other compounds having a vinyl unsaturated group (B) are trimethylolpropyl triacrylate, EO-modified trimethylolpropyl triacrylate, PO-modified trimethylolpropyl triacrylate, pentaerythritol triacrylate, pentaerythritol tetraacrylate, dipentaerythritol hexaacrylate, dipentaerythritol pentaacrylate, dipentaerythritol tetraacrylate, caprolactone-modified dipentaerythritol hexaacrylate, di(trimethylolpropyl)tetraacrylate, PO-modified glycerol triacrylate, or a combination thereof.

Based on the alkali-soluble resin (A) as 100 parts by weight, the amount of the compound having a vinyl unsaturated group (B) is 10 parts by weight to 100 parts by weight, preferably is 15 parts by weight to 90 parts by weight, and more preferably is 20 parts by weight to 80 parts by weight.

### Photo Initiator (C)

There is no specific limitation to the photo initiator (C) of the present invention, and the photo initiator (C) can include but is not limited to, O-acyloxime compounds, triazine compounds. acetophenone compounds, biimdazole compounds benzophenone compounds, α-diketone compounds, acyloin compounds, acyloin ether compounds, acylphosphine oxide compounds, quinone compounds, halogen-containing compound, peroxides, or the like.

Specific examples of the above-mentioned O-acyloxime compounds can include but is not limited to 1-[4-phenylthio)phenyl]-heptane-1,2-dione-2-(O-benzoyloxime), 1-[4- phenylthio)phenyl]-octane-1,2-dione-2-(O-benzoyloxime), 1-[4-(benzoyl)phenyl]-heptane-1,2-dione-2-(O-benzoyloxime), 1-[9-ethyl-6-(2-methylbenzoyl)-9H-carbazol-3-yl]-ethylketo-1-(O-acetyloxime). 1-[9-ethyl-6-(3-methylbenzoyl)-9H-carbazol-3-yl]ethylketo-1-(O-acetyloxime), 1-[9-ethyl-6-benzoyl-9H-carbazol-3-yl]ethylketo-1-(O-acetyloxime), ethylketo-1-[9-ethyl-6-(2-methyl-4-tetrahydrofurylbenzoyl)-9H-carbazol-3-yl]-1-(O-acetyloxime), ethylketo-1-[9-ethyl-6-(2-methyl-5-tetrafurylbenzoyl)-9H-carbazol-3-yl]-1-(O-acetyloxime), ethyketo-1-[9-ethyl-6-(2-methyl-4-tetrapyranylbenzoyl)-9H-carbazol-3-yl]-1-(O-acetyloxime), ethylketo-1-[9-ethyl-6-(2-methyl-4-tetrafurylmethoxybenzoyl)-9H-carbazol-yl]-1-(O-acetyloxime), ethylketo-1-[9-ethyl-6-2-methyl-4-tetrapyranylmethoxybenzoyl -9H-carbazol-3-yl]-1-(O-acetyloxime), ethylketo-1-[9-ethyl-6-(2-methyl-5-tetrafurylmethoxybenzoyl)-9H-carbazol-3-yl]-1-(O-acetyloxime), ethylketo-1-[9-ethyl-6-(2-methyl-5-tetrapyranylmethoxybenzoyl)-9H-carbazol-3-yl]-1-(O-acetyloxime), ethylketo-1-{9-ethyl-6-[2-methyl-4-(2,2-dimethyl-1,3-dioxolyl)benzoyl]-9H-carbazol-3-yl}-1-(O-acetyloxime), ethylketo-1-{9-ethyl-6-[2-methyl-4-(2,2-dimethyl-1,3-dicixolyl)methoxybenzoyl]-9H-1-carbazol-3-yl}-1-(O-acetyloxime), or the like.

The above-mentioned O-acyloxime compounds preferably are 1-[4-(phenylthio)phenyl]-octane-1,2-dione-2-(O-benzoyloxime) (such as OXE 01 manufactured by Ciba Specialty Chemicals), 1-[9-ethyl-6-(2-methylbenzoyl)-9H-carbazol-3-yl]-ethylketo-1-(O-acetyloxime) (such as OXE 02 manufactured by Ciba Specialty Chemicals), ethylketo-1-[9-ethyl-6-(2-methyl-4-tetrahydrofurylbenzoyl)-9H-carbazol-3-yl]-1-(O-acetyloxime), ethylketo-1-{9-ethyl-6-[2-methyl-4-(2,2-dimethyl-1,3-dioxolyl)methoxybenzoyl]-9H-carbazol-3-yl}-1-(O-acetyloxime), or the like. The above-mentioned O-acyloxime compounds can be used alone or in a combination of two or more.

The above-mentioned triazine compounds may include but is not limited to vinyl-halomethyl-s-triazine compounds, 2-(naphtho-1-yl)-4,6-bis-halornethyl-s-triazine compounds, 4-(p-aminophenyl)-2,6-di-halomethyl-s-triazine compounds, or the like.

The above-mentioned vinyl-halomethyl-s-triazine compounds may include but is not limited to 2,4-bis(trichloromethyl)-6-p-methoxystyryl-s-triazine, 2,4-bis(trichloromethyl)-3-(1-p-dimethylaminophenyl-1,3-butadienyl)-s-triazine, 2-trichloromethyl-3-amino-6-p-methoxystyryl-s-triazine, or the like.

The above-mentioned 2-(naphtho-1-yl)-4,6 bis-halomethyl-s-triazine compounds may include but is not limited to 2-(naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-[4-(2-methoxyethyl)-naphtho-1-yl]-4,6-bis-trichloromethyl-s-triazine, 2-[4-(2-ethoxyethyl)-naphtho-1-yl]-4,6-bis-trichloromethyl-s-triazine, 2-[4-(2-butoxyethyl-naphtho-1-yl)4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6 bis-trichloromethyl-s-triazine, 2-(6-methoxy-naphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, or the like.

The aforementioned 4-(p-aminophenyl)-2,6-di-halomethyl-s-triazine compounds may include but is not limited to 4-[p-N,N-di(ethoxycarbonylmethyl)aminophenyl]-2,6-di(trichloromethyl)-s-triazine, 4-[o-methyl-p-N,N-di(ethoxycarbonylmethyl)aminophenyl]-2,6-di(trichloromethyl)s-triazine, 4-[p-N,N-di(chloroethyl)aminophenyl]-2,6-di(trichloromethyl-triazine, 4-[o-methyl-p-N,N-di(chloroethyl)aminophenyl]-2,6-di(trichloromethyl)-s-triazine, 4-[p-N-chloroethylaminophenyl]-2,6-di(trichloromethyl)-s-triazine, 4-[p-N-ethoxycarbonylmethylaminophenyl]-2,6-di(trichloromethyl)-s-triazine, 4-[p-N,N-di(phenyl)aminophenyl]-2,6-di(trichloromethyl)-s-triazine, 4-[p-N-chloroethylcarbonylaminophenyl]-2,6-di(trichloromethyl)-s-triazine, 4-[p-N-(p-methoxyphenyl)carbonylaminophenyl]-2,6-di(trichloromethyl)-s-triazine, 4-[m-N,N-di(ethoxycarbonylmethyl)aminophenyl]-2,6-di(trichloromethyl)-s-triazine, 4-[m-bromo-p-N,N-di(ethoxycarbonylmethyl)aminophenyl]-2,6-di(richloromethyl)-s-triazine, 4-[m-chloro-p-N,N-di(ethoxycarbonylmethyl)aminophenyl]-2,6-di(trichloromethyl)-s-triazine, 4-[m-fluoro-p-N,N-di(ethoxycarbonylmethyl)aminophenyl]-2,6-di(trichloromethyl)-s-triazine, 4-[o-bromo-p-N,N-di(ethoxycarbonylmethyl)aminophenyl]-2,6-di(trichloromethyl)-s-triazine, 4-[o-chloro-p-N,N-di(ethoxycarbonylmethyl)aminophenyl]-2,6-di(trichloromethyl)-s-triazine, 4-[o-fluoro-p-N,N-di(ethoxycarbonylmethyl)aminophenyl]-2,6-di(trichloromethyl)-s-triazine, 4-[o-bromo-p-N,N-di(chloroethyl)aminophenyl]-2,6-6(trichloromethyl)-s-triazine, 4-[o-chloro-p-N,N-di(chloroethyl)aminophenyl]-2,6-di(trichloromethyl)-s-triazine, 4-[o-fluoro-p-N,N-di(chloroethyl)aminophenyl]-2,6-di(trichloromethyl)-s-triazine, 4-[m-bromo-p-N,N-di(chloroethyl)aminophenyl]-2,6-diarichloromethyl)-s-triazine, 4-[m-chloro-p-N,N-di(chloroethyl)aminophenyl]-2,6-di(trichloromethyl)-s-triazine, 4-[m-fluoro-p-N,N-di(chloroethyl)aminophenyl]-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethylaminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophanyl)-2,6-di(trichloromethyl)-s-triazine, 4-(o-chloro-p-N-chloroethylaminophenyl)-2,6-di(trichloromethyl)-s-triazine, 4-(o-fluoro-p-N-chloroethylaminophenyl)-2,6-di(trichloromethyl)-s-triazine, 2,4-bis(trichloromethyl)-6-{3-bromo-4-[N,N-di(ethoxycarbonylmethyl)amino]phenyl}-1,3,5-triazine, or the like.

The above-mentioned triazine compounds can be used alone or in a combination of two or more. Preferably, the above-mentioned triazine compounds are 4-[m-bromo-p-N,N-di(ethoxycarbonylmethyl)aminophenyl]-2,6-di(trichloromethyl)-s-triazine, 2,4-bis(trichloromethyl)-6-p-methoxystyryl-s-triazine or the like.

The above-mentioned acetophenone compounds may include but is not limited to p-dimethylamino-acetophenone, α,α′-dimethoxyazoxyacetophenone, 2,2′-dimethyl-2-phenylacetophenone, p-methoxyacetophenone, 2-methyl-1-[4-(methylthio)phenyl]-2-morpholino-1-propanone, 2-benzyl-2-N,N-dimethylamino-1-(4-morpholinophenyl)-1-butanone, or the like. The acetophenone compounds can be used alone or in a combination of two or more.

Preferably, the acetophenone compounds may be 2-methyl-1-[4-(methylthio)phenyl]-2-morpholino-1-propanone or 2-benzyl-2-N,N-dimethylamino-1-(4-morpholinophenyl)-1-butanone,

The above-mentioned biimidazole compounds may include but is not limited to 2,2′-bis(o-chlorophenyl)-4,4′,5,5′-tetraphenylbiimidazole, 2,2′-bis(o-fluorophenyl)-4,4′,5,5 -tetraphenylbiimidazole, 2,2′-bis(o-methylphenyl)-4,4′,5,5′-tetraphenylbiimidazole, 2,2-bis(o-methoxyphenyl)-4,4′,5,5′-tetraphenylbiimidazole, 2,2′-bis(o-ethylphenyl)-4,4′,5,5′-tetraphenylbiimidazole, 2,2′-bis(p-methoxyphenyl)-4,4′,5,5′-tetraphenylbilmidazole, 2,2 -bis(2,2′,4,4′-tetramethoxyphenyl)-4,4′,5,5′-tetraphenyibiimidazole, 2,2′-bis(2-chlorophenyl)-4,4′,5,5′-tetraphenylbiimidazole, 2,2′-bis(2,4-dichlorophenyl)-4,4′,5,5′-tetraphenylbilmidazole, or the like. The biimidazole compounds can be used alone or in a combination of two or more. Preferably, the biimidazole compounds may be 2,2′-bis(2,4-dichlorophenyl)-4,4′,5,5′-tetraphenylbilmidazole.

The above-mentioned benzophenone compounds may include but is not limited to thioxanthone, 2,4-diethylthioxanthone, thioxanthone-4-sulfone, benzophenone, 4,4′-bis(dimethylamino)benzophenone, 4,4′-bis(diethylamino)benzophenone, or the like. The above-mentioned benzophenone compounds can be used alone or in a combination of two or more. Preferably, the above-mentioned benzophenone compounds are 4,4′-bis(diethylamino)benzophenone.

The above-mentioned α-diketone compounds may include but is not limited to benzil, acetyl, or the like. The above-mentioned acyloin compounds may include but is not limited to benzoin. The above-mentioned acyloin ether compounds may include but is not limited to benzoin methyl ether, benzoin ethyl ether, benzoin isopropyl ether, or the like. The above-mentioned acylphosphine oxide compounds may include but is not limited to 2,4,6-trimethyl-benzoyldiphenylphosphine oxide, bis-(2,6-dimethoxybenzoyl)-2,4,4-trimethylbenzylphosphine oxide, or the like. The above-mentioned quinone compounds may include but is not limited to anthraquinone, 1,4-naphthoquinone, or the like. The above-mentioned halogen-containing compounds may include but is not limited to phenacyl chloride, tribromomethylphenylsulfone, tris(trichloromethyl)-s-triazine, or the like. The above-mentioned peroxides may include but is not limited to di-tertbutylperoxide, or the like. The above-mentioned a-diketone compounds, acyloin compounds, acyloin ether compounds, acylphosphine oxide compounds, quinone compounds, halogen-containing compounds, peroxides and the like can be used alone or in a combination of two or more.

The amount of the photo initiator (C) of the present invention used can be adjusted according to the requirements, based on the alkali-soluble resin (A) as 100 parts by weight, the amount of the photo initiator (C) is 5 parts by weight to 50 parts by weight, preferably is 7 parts by weight to 45 parts by weight, and more preferably is 10 parts by weight to 40 parts by weight.

### Solvent (D)

The solvents (D) of the present invention are preferably those that can dissolve the alkali-soluble resin (A), the compound having a vinyl unsaturated group (B), and the photo initiator (C), and the solvents do not react with the above-mentioned components and have an appropriate volatility.

The solvent (D) may include but is not limited to alkylene glycol monoalkyl ether compounds such as ethylene glycol monomethyl ether, ethylene glycol monoethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether and the like; alkylene glycol monoalkyl ether acetate compounds such as ethylene glycol monomethyl ether acetate, ethylene glycol monoethyl ether acetate, propylene glycol monomethyl ether acetate, propylene glycol monoethyl ether acetate and the like; ether compounds such as diethylene glycol dimethyl ether, diethylene glycol methyl ethyl ether, diethylene glycol diethyl ether, tetrahydrofuran and the like; ketone compounds such as methyl ethyl ketone, cyclohexanone, 2-heptanone, 3-heptanone, diacetone alcohol and the like; alkyl lactate compounds such as methyl lactate, ethyl lactate and the like; other ester compounds such as methyl 2-hydroxy-2-methylpropionate, ethyl 2-hydroxy-2-methylpropionate methyl 3-methoxypropionate, ethyl 3-methoxypropionate, methyl 3-ethoxypropionate, ethyl 3-ethoxypropionate, ethyl ethoxy acetate, ethyl hydroxy acetate, methyl 2-hydroxy-3-methylbutyrate, 3-methyl-3-methoxybutyl acetate, 3-methyl-3-methoxybutyl propionate, ethyl acetate, n-propyl acetate, iso-propyl acetate, n-butyl acetate, iso-butyl acetate, n-amyl acetate, iso-amyl acetate, n-butyl propionate, ethyl butyrate, n-propyl butyrate, iso-propyl butyrate, n-butyl butyrate, methyl pyruvate, ethyl pyruvate, n-propyl pyruvate, methyl acetoacetate, ethyl acetoacetate, ethyl 2-oxobutyrate and the like; aromatic hydrocarbon compounds such as toluene, xylene and the like; and carboxylic acid amide compounds such as N-methylpyrrolidone, N,N-dimethylformamide, N,N-dimethylacetamide and the like; or any combination of the above-mentioned compounds. The above-mentioned solvents (D) can be used alone or in a combination of two or more.

Based on the alkali-soluble resin (A) as 100 parts by weight, the amount of solvent (D) is 500 parts by weight to 5000 parts by weight, preferably is 800 parts by weight to 4500 parts by weight, and more preferably is 1000 parts by weight to 4000 parts by weight.

### Black Pigment (E)

Preferably, the black pigment (E) of the present invention is a black pigment having heat resistance, light resistance and solvent resistance.

The above-mentioned black pigment (E) may include but is not limited to black organic pigments such as perylene black, cyanine black, aniline black and the like; organic pigments with near-black color mixture formed by mixing at least two pigments selected from the group consisting of red, blue, green, purple, yellow, cyanine, magenta and the like pigments; light-shielding materials such as carbon black, chromium oxide, iron oxide, titanium black, graphite and the like.

The above-mentioned carbon black can include but is not limited to C.I. pigment black 7 and the like (for example MA100, MA230, MA8, #970, #1000, #2350, #2650 and the like, commercially available products manufactured by Mitsubishi Chemical Co.). The above-mentioned black pigment (E) can be used alone or in a combination of two or more.

Based on the alkali-soluble resin (A) as 100 parts by weight, the amount of black pigment (E) is 100 parts by weight to 800 parts by weight, preferably is 120 parts by weight to 700 parts by weight, and more preferably is 150 parts by weight to 600 parts by weight.

### Additive (F)

The photosensitive resin composition of the present invention can include additives (F) without affecting the effect of the present invention. The additives (F) can include but is not limited to a surfactant, a filler, an adhesion promoting agent, a cross-linking agent, an antioxidant, an anti-coagulant, other polymers [for example, polymers other than the alkali-soluble resin (A)] that can enhance various properties (for example, mechanical properties) and the like.

The above-mentioned surfactant can be selected from the group consisting of cationic, anionic, nonionic, amphoteric, polysiloxane, fluorine surfactants or a combination thereof. The surfactant can include but is not limited to polyoxyethylene alkyl ether compounds such as polyoxyethylene dodecyl ether, polyoxyethylene stearyl ether, polyoxyethylene oleyl ether and the like; polyoxyethylene alkyl phenyl ether compounds such as polyoxyethylene octyl phenyl ether, polyoxyethylene nonyl phenyl ether and the like; polyethylene glycol diester compounds such as polyethylene glycol dilaurate, polyethylene glycol distearate and the like; sorbitan fatty acid ester compounds; fatty acid-modified polyester compounds; or tertiary amine-modified polyurethane compounds. The above-mentioned surfactant can be used alone or in a combination of two or more.

Specific examples of the above-mentioned surfactants are KP manufactured by Shin-Etsu Chemical Industry Co. Ltd.; SF-8427 manufactured by Toray Dow Corning Silicon Co. Ltd.; Polyflow manufactured by Kyoeisha Oil Chemical Co. Ltd.; F-Top manufactured by Tochem Product Co. Ltd.; Megafac manufactured by Dainippon Ink and Chemicals Co. Ltd.; Fluorade manufactured by Sumitomo 3M Co. Ltd.; Asahi Guard or Surflon manufactured by Asahi Glass Co. Ltd,; and SINOPOL E8008 manufactured by Sino-Japan Chemical. Co. Ltd.; and the like.

The above-mentioned filler can include but is not limited to glass, aluminum and the like.

The above-mentioned adhesion promoting agent can include but is not limited to vinyltrimethoxysilane, vinyltriethoxysilane, vinyl tris(2-methoxyethoxy)silane, N-(2-aminoethyl)-3-aminopropylmethyl dimethoxysilane, N-(2-aminoethyl)-3-aminopropyl trimethoxysilane, 3-aminopropyl triethoxysilane, 3-glycidolypropyl trimethoxysilane, 3-glycidolpropylmethyl diethoxysilane, 2-(3,4-epoxycyclohexyl)ethyl trimethoxysilane, 3-chloropropylmethyl dimethoxysilane, 3-chloropropyl trimethoxysilane, 3-methacryloxypropyl trimethoxysilane, 3-mercaptopropyl trimethoxysilane or the like.

The above-mentioned antioxidant can include but is not limited to 2,2-thio bis(4-methyl-6-t-butylphenol) or 2,6-di-butylphenol or the like.

Specific example of the anti-coagulant is sodium polyacrylate or the like.

Specific examples of the cross-linking agent can include but is not limited to epoxy compounds or resins, such as 1031S, 157S-70 or the like manufactured by Japan Epoxy Resins Co. Ltd.

Based on the alkali-soluble resin (A) as 100 parts by weight, the amount of the aforementioned filler, adhesion promoting agent, antioxidant, anti-coagulant, and polymers other than the alkali-soluble resin (A) is 0 to 10 parts by weight, and preferably is 0 to 6 parts by weight.

Based on the alkali-soluble resin (A) as 100 parts by weight, the amount of the aforementioned surfactant is 0 to 6 parts by weight, and preferably is 0 to 4 parts by weight.

Based on the alkali-soluble resin (A) as 100 parts by weight, the amount of the aforementioned cross-linking agent is 0 to 100 parts by weight, and preferably is 0 to 80 parts by weight.

### Preparation of Photosensitive Resin Composition

The photosensitive resin composition of the present invention is prepared by placing the above-mentioned alkali-soluble resin (A), the compound having a vinyl unsaturated group (B), the photo initiator (C), the solvent (D) and the black pigment (E) in a mixer and uniformly mixed to form a solution. Additives (F) such as surfactant, filler, adhesion promoting agent, antioxidant, UV absorbers or anti-coagulant and other polymers that can enhance various properties (such as mechanical properties) may also be optionally added if necessary.

There is no specific limitation to the preparation method for the photosensitive resin composition of the present invention, for example: the black pigment (E) may be directly added and dispersed into the photosensitive resin composition, or parts of the black pigment (E) can also be dispersed in a medium beforehand to form a pigment dispersion liquid, and the medium includes parts of the alkali-soluble resin (A) and the solvent (D). Afterwards, the pigment dispersion liquid is mixed with the compound having a vinyl unsaturated group (B), the photo initiator (C) and the remaining alkali-soluble resin (A) and the solvent (C) to form the photosensitive resin composition. The aforementioned dispersion step of the black pigment (E) may be preformed via mixers such as beads mill, roll mill or the like, to mix the above-mentioned ingredients.

### Preparation of Black Matrix

The black matrix of the present invention is prepared by sequentially prebaking, exposing, developing and post exposure baking the above-mentioned photosensitive resin composition.

The thickness of the film of the prepared black matrix varies according to the application. When the black matrix is used in a liquid crystal display device, the thickness of the film of the black matrix may be 0.8 μm to 1.2 μm. When the black matrix is applied in a touch panel, the thickness of the film of the black matrix may be 1.5 μm to 2.5 μm. When the thickness of the film is 1 μm, the optical density of the black matrix is more than 3.0, preferably is 3.2 to 5.5, and more preferably is 3.5 to 5.5.

The black matrix can via spin coating, slit coating, and the like. The above-mentioned photosensitive resin composition is coated onto the substrate, and then the solvent is removed by drying under reduced pressure or prebaked treatment, thereby forming a prebaked coating film on the substrate. The process conditions for drying under reduced pressure and prebaked treatment depends on the type and the formulating ratio of each component. The drying under reduced pressure is usually at a pressure less than 200 mmHg for 1 second to 20 seconds, and the prebaking is usually at 70° C. to 110° C. for 1 minute to 15 minutes. Afterwards, the coating film is exposed under a specified photomask, and immersing in a developer at 21° C. to 25° C. for 15 seconds to 5 minutes to remove the unwanted parts, thereby forming a specific pattern. The light used for the exposure is preferably ultraviolet light such as g-line, h-line, i-line, and the like. The device for providing the ultraviolet light can be a (ultra-)high pressure mercury lamp, or a metal halide lamp.

The developer used in preparing the black matrix may include but is not limited to alkali compounds such as sodium hydroxide, potassium hydroxide, sodium carbonate, sodium hydrogen carbonate, potassium carbonate, potassium hydrogen carbonate, sodium silicate, sodium methylsilicate, aqueous ammonia, ethylamine, diethylamine, dimethyl ethanolamine, tetramethylammonium hydroxide,tetraethylammonium hydroxide, choline, pyrrole, piperidine, or 1,8-diazabicyclo-[5,4,0]-7-undecene. The concentration of the developer is 0.001 wt % to 10 wt %, preferably is 0.005 wt % to 5 wt %, and more preferably is 0.01 wt % to 1 wt %.

When the developers containing the aforementioned alkali compounds are applied, the pattern is generally washed by water after development, and dried by compressed air or nitrogen gas. Next, a post-bake treatment was performed by a hot plate an oven or other heating devices, and the temperature is usually at 150° C. to 250° C. The heating period is 5 minutes to 60 minutes on the hot plate, or the heating period is 15 minutes to 150 minutes in the oven. After the above steps the black matrix can be formed.

The substrates used for preparing the black matrix can be glasses used in liquid crystal devices such as alkali-free glass, soda-lime glass, hard glass (Pyrex glass), quartz glass, glasses coated with a transparent conductive film, a photoelectric conversion substrate (for example, a silicon substrate) used in a solid-state image sensor, and the like.

### Preparation of Color Filter

The method for forming the color filter of the present invention can be a method such as spin coating, cast coating, roll coating and the like, and the aforementioned photosensitive resin composition for a color filter is coated onto a substrate. The black matrix for separating each pixel colored layer has already formed on the substrate, and the black matrix is formed by the aforementioned photosensitive resin composition. After coating, most of the solvents are removed by drying under reduced pressure, then the remaining solvents are removed by prebake treatment, thus forming a prebaked coating film.

The conditions for the aforementioned drying under reduced pressure or prebake treatment are adjusted depends on the type and the formulating ratio of each component. Typically, the drying under reduced pressure is at 0 mmHg to 200 mmHg for 1 second to 60 seconds, and the prebake treatment is carried out at 70° C. to 110° C. for 1 minute to 15 minutes. After the prebake treatment, the prebaked coating film is exposed under a specified mask, and then immersing in the developer at 21° C. to 25° C. to develop for 15 seconds to 5 minutes to remove the unwanted parts and thereby forming a specified pattern. The light used for the above-mentioned exposure step is preferably ultraviolet light such as g-line, h-line, i-line, and the like, the device for providing the ultraviolet light can be a (ultra-)high pressure mercury lamp, or a metal halide lamp.

After development, the pattern was washed by water, and then the pattern is dried by compressed air or nitrogen gas. Next, the post-bake treatment is performed by the heating device such as the hot plate, the oven or the like. The conditions of the post-bake treatment are the same as above, therefore not repeated here again.

The pixel layer of the color filter is constituted by the photosensitive resin compositions of each colors (mainly including red, green and blue), and the photosensitive resin compositions of each colors are formed by repeating the aforementioned steps. Next, an evaporated indium-tin oxide (ITO) film can be formed on the pixel layer at 220° C. to 250° C. in a vacuum environment. If necessary, after the ITO film is etched and wired, a polyimide for a LC alignment film can be coated on the ITO film and further be burnt, thereby forming the color filter for a LCD device.

### Preparation of Liquid Crystal Display Devices

The LCD device of the present invention includes the above-mentioned color filter.

The LCD device of the present invention can be formed by the following method, for example: the color filter formed by the above-mentioned color filter preparation method and a driving substrate with thin film transistors (TFT) is arranged in a way to oppose each other with a space (cell gap) in between. The peripheral portions of the two substrates are joined together with a sealing agent, and liquid crystals are injected into the cell gap defined by the surfaces of the substrates and the sealing agent, the injection hole was sealed up to form a liquid crystal cell. Then, a polarizer was affixed to the outer surface of the liquid crystal cell, i.e. the other sides of the liquid crystal cell, thereby obtaining the liquid crystal display device.

The aforementioned liquid crystal can be a liquid crystal compound or liquid crystal composition, wherein the specific composition is not particularly limited, it can be any liquid crystal compound and composition well know to any person having ordinary skills in this art.

Furthermore, the type of the above-mentioned liquid crystal alignment film used for restricting the orientation of the liquid crystal molecules is not particularly limited and can be any inorganic or organic substance. In addition, methods for forming the liquid crystal alignment film is well known to a person having ordinary skills in this art, thus not described here.

Various applications of the present invention will be described in more details referring to several exemplary embodiments below, and are not intended to be limiting. Thus, one skilled in the art can easily ascertain the essential characteristics of the present invention and, without departing from the spirit and scope thereof, can make various changes and modifications of the invention to adapt it to various usages and conditions.

### DETAILED DESCRIPTION

### Preparation of Alkali-Soluble Resin (A)

### Preparation of Resin Having an Unsaturated Group (A.1)

### Synthesis Example 1

100 parts by weight of fluorene epoxy compound (ESF-300, manufactured by Nippon Steel Chemical Co.; epoxy equivalent: 231), 30 parts by weight of acrylic acid, 0.3 parts by weight of benzyltriethylammonium chloride, 0.1 parts by weight of 2,6-di-t-butyl-p-cresol, and 130 parts by weight of propylene glycol monomethyl ether acetate were added into a 500 ml four-necked flask in a continuous manner, and controlled at a feeding rate of 25 parts by weight/min. The temperature is maintained at 100° C. to 110° C., after reacting for a period of 15 hours, a light yellowish transparent mixture solution with a solid concentration of 50 wt % can be obtained.

Next, 100 parts by weight of the above mixture solution was dissolved in 25 parts by weight of ethylene glycol monoethyl ether acetate, and 6 parts by weight of tetrahydrophthalic anhydride and 13 parts by weight of benzophenone tetracarboxylic dianhydride were added at the same time, so as to form a solution. The solution was heated to 110° C. to 115° C. to subject to a reaction. After 2 hours, a resin having unsaturated group (A-1-1) with an acid value of 98.0 mgKOH/g can be obtained.

### Synthesis Example 2

100 parts by weight of fluorene epoxy compound (ESF-300, manufactured by Nippon Steel Chemical Co.; epoxy equivalent: 231), 30 parts by weight of acrylic acid, 0.3 parts by weight of benzyltriethylammonium chloride, 0.1 parts by weight of 2,6-dibutyl-p-cresol, and 130 parts by weight of propylene glycol monomethyl ether acetate were added into a 500 ml four-necked flask in a continuous manner, and controlled at a feeding rate of 25 parts by weight/min. The temperature is maintained at 100° C. to 110° C., after reacting for a period of 15 hours, a light yellowish transparent mixture solution with a solid concentration of 50 wt % can be obtained.

Next, 100 parts by weight of the above-mentioned mixture solution was dissolved in 25 parts by weight of ethylene glycol monoethyl ether acetate, and 13 parts by weight of benzophenone tetracarboxylic dianhydride was added, so as to form a solution. The solution was reacted at 90° C. to 95° C. for 2 hours. After 6 parts by weight of tetrahydrophthalic anhydride was added, the solution as reacted at 90° C. to 95° C. for 4 hours to obtain a resin having unsaturated group (A-1-2) with an acid value of 99.0 mgKOH/g,

### Synthesis Example 3

400 parts by weight of epoxy compound (NC-3000, manufactured by Nippon Kayaku Co. Ltd.; epoxy equivalent: 288), 102 parts by weight of acrylic acid, 0.3 part by weight of p-methoxyphenol, 5 parts by weight of triphenyl phosphine, and 264 parts by weight of propylene glycol monomethyl ether acetate were placed in a reaction flask and subjected to a reaction. The temperature of the reaction was maintained at 95° C. for 9 hours to obtain an intermediate product with an acid value of 2.2 mgKOH/g. Next, 151 parts by weight of tetrahydrophthalic anhydride was added and reacted at 95° C. for 4 hours to obtain a resin having unsaturated group (A-1-3). An acid value of the resin having unsaturated group (A-1-3) is 102 mgKOH/g and an average molecular weight is 3,200.

### Preparation of Other Alkali-soluble Resin (A-2)

### Synthesis Example 4

1 parts by weight of 2,2′-azobisisobutyronitrile, 240 parts by weight of propylene glycol monomethyl ether acetate, 20 parts by weight of methacrylic acid, 15 parts by weight of styrene, 35 parts by weight of benzoyl methacrylate, 10 parts by weight of glyceryl monomethyl acrylate, and 20 parts by weight of N-phenyl maleimide were added in a reaction flask with a stirrer and a condenser installed, and the reaction flask was filled with nitrogen. Afterwards, the temperature was slowly raised to 80° C., to uniformly mix the reactants and polymerize for 4 hours. Next, the temperature was further slowly raised to 100° C. and 0.5 parts by weight of 2,2′-azobisisobutyrontrile was added. After the polymerized reaction was performed 1 hour, an alkali-soluble (A-2-1) was obtained.

### Synthesis Example 5

2 parts by weight of 2,2′-azobisisobutyronitrile 300 parts by weight of dipropylene glycol monomethyl ether, 15 parts by weight of methacrylic acid, 15 parts by weight of 2-hydroxyethyl acrylate and 70 parts by weight of benzoyl methacrylate was placed in a reaction flask with a stirrer and a condenser installed, and the reaction flask was filled with nitrogen. Afterwards, the temperature was slowly raised to 80° C. to uniformly mix the reactants and polymerize for 3 hours. Next, the temperature was further slowly raised to 100° C. and 0.5 parts by weight of 2,2′-azobisisobutyronitrile was added. After the polymerized reaction was performed 1 hour, an alkali-soluble (A-2-2) was obtained.

### Preparation of Photosensitive Resin Composition

The following photosensitive resin compositions of Embodiments 1 to 8 and Comparative Embodiments 1 to 3 are prepared according to Table 1.

### Embodiment 1

100 parts by weight of the resin having unsaturated group (A-1-1) of synthesis example 1, 1 part by weight of compound (hereinafter referred to as B-1-1) manufactured by Shin-Nakamura Chemical Co. Ltd. and the trade name is NK Ester A-BPE-10, 9 parts by weight of trimethylolpropyl triacrylate, 5 parts by weight of 1-[9-ethyl-6-(2-methylbenzoyl)-9H-carbazol-3-yl]-ethylketo-1-(O-acetyloxime) (trade name is OXE02, manufactured by Ciba Specialty Chemicals Co.; hereinafter referred to as C-1), 500 parts by weight of propylene glycol methyl ether acetate (hereinafter referred to as D-1), and 100 parts by weight of black pigments manufactured by Mitsubishi Chemical Co. (trade name MA100; hereinafter referred to as E-1) were formed in a homogeneous solution state by a shaking agitator, so as to obtain a photosensitive resin composition of Embodiment 1. The photosensitive resin composition was evaluated by the following evaluation method and the result is shown in Table 1. The evaluation method of reliability is described later.

### Embodiments 2 to 8 and Comparative Embodiments 1 to 3

Embodiments 2 to 8 and Comparative Embodiments 1 to 3 uses the same method as Embodiments 1 to prepare the photosensitive resin composition, the difference is that in Embodiments 2 to 8 and Comparative Embodiments 1 to 3, the type and amount of the raw materials of the photosensitive resin composition were changed, the formulation and evaluation results are shown in Table 1, thus not repeated here again.

### Preparation of Black Matrix

The photosensitive resin compositions of the above Embodiments 1 to 8 and Comparative Embodiments 1 to 3 were spin-coated onto a glass substrate of 100 mm×100 mm by a coater (MS-A150, purchased from MIKASA. Co., Tokyo, Japan). The substrate was dried under a reduced pressure of 1 mmHg for 5 seconds. Next, the substrate was prebaked at 100° C. for 2 minutes to form a prebaked film with a thickness of 1.2 μm. Then, the prebaked film was irradiated with ultra-violet light by an exposure machine (Model No. AG500-4N, manufactured by M&R Nano Technology; the intensity of the ultra-violet light is 100 mJ/cm²). And then, the prebaked film was immersed in a developer (0.04% potassium hydroxide solution) at 23° C. After 1 minute, the substrate was washed by pure water and then baked at 230° C. for 30 minutes, so as to obtain a black matrix formed on the glass substrate with a thickness of 1.0 μm.

### Evaluation Methods

### Reliability

The black matrix formed by the photosensitive resin composition of the Embodiments 1 to 8 and Comparative Embodiments 1 to 3 was placed in a oven at 121° C., 2 atm pressure and 100% relative humidity for 56 hours. According to the adhesiveness testing method, JIS.5400(1900)8.5, the aforementioned black matrix was cut to 100 grid patterns by a knife. Next, the grid patterns were adhered by a tape, and then the tape was removed. An evaluation was made according to the residual grid patterns and the following criterion.

⊚: 5B.

◯: 4B.

Δ: 3B to 2B.

×: 1B to 0B.

Wherein, 5B: the grid patterns do not fall.
4B: 0%<the amount of the fallen grid patterns≦5%.
3B: 5%<the amount of the fallen grid patterns≦15%.
2B: 15%<the amount of the fallen grid patterns≦35%.
1B: 35%<the amount of the fallen grid patterns≦65%.
0B: 65%<the amount of the fallen grid patterns≦100%.

From the results of Table 1, when the photosensitive resin composition contains resin having an unsaturated group (A-1) and the compound having an unsaturated group (B-1), the photosensitive resin composition has good reliability in the environment of high temperature and high humidity.

Furthermore, when the alkali-soluble resin (A) of the photosensitive resin composition contains the resin having an unsaturated group (A-1), the photosensitive resin composition has good reliability in the environment of high temperature and high humidity. Based on the alkali-soluble resin (A) as 100 parts by weight, the amount of the resin having an unsaturated group (A-1) is 30 parts by weight to 100 parts by weight.

In addition, when the compound having a vinyl unsaturated group (B) of the photosensitive resin composition contains a compound (B-1) shown in formula (1), the product photosensitive resin composition has good reliability under high temperature and high humidity, wherein based on 100 parts by weight of the amount of alkali-soluble resin (A) used, the amount of compound (B-1) shown in formula (I) used is 1 parts by weight to 15 parts.

Furthermore, it is worth mentioning that specific compounds, specific compositions, specific reaction conditions, specific processes, specific evaluation methods or specific instruments are employed as exemplary embodiments in the present invention for illustrating the photosensitive resin composition, the color filter and liquid crystal display device in the present invention, as is understood by a person skilled in the art, the invention is not limited thereto, without departing from the spirit and scope of the present invention, the photosensitive resin composition, the color filter and liquid crystal display device in the present invention can include other compounds, other compositions, other reaction conditions, other processes, other evaluation methods or other instruments rather than limited to the aforementioned examples.

Although the present invention has been described in considerable detail with reference to certain embodiments thereof, other embodiments are possible. It will be apparent to those skilled in the art that various modifications and variations can be made to the present invention without departing from the scope or spirit of the invention. Therefore, the spirit and scope of the appended claims should not be limited to the description of the embodiments contained herein.

TABLE 1

| | | | Embodiments | | | | | | | | Comparative Embodiments | | |
|---|---|---|---|---|---|---|---|---|---|---|---|---|---|
| Component: | | | 1 | 2 | 3 | 4 | 5 | 6 | 7 | 8 | 1 | 2 | 3 |
| Alkali-soluble resin (A) | A-1 | A-1-1 | 100 | | | 30 | | | 50 | 100 | | 100 | |
| (parts by weight) | | A-1-2 | | 100 | | | 50 | | 50 | | | | |
| | | A-1-3 | | | 100 | | | 80 | | | | | |
| | A-2 | A-2-1 | | | | 70 | | 20 | | | 100 | | |
| | | A-2-2 | | | | | 50 | | | | | | 100 |
| Compound having a vinyl | B-1 | B-1-1 | 1 | | 2 | | | | | | 6 | | |
| unsaturated group (B) | | B-1-2 | | 2 | | | | | 0.5 | | | | |
| (parts by weight) | | B-1-3 | | | 2 | | | | | 20 | | | |
| | | B-1-4 | | | | 8 | | | | | | | |
| | | B-1-5 | | | | | 12 | | | | | | |
| | | B-1-6 | | | | | | 15 | | | | | |
| | B-2 | B-2-1 | 9 | | | 30 | | | | | 34 | | 60 |
| | | B-2-2 | | 18 | | | 45 | | 70 | | | 50 | |
| | | B-2-3 | | | 22 | | | 85 | | | | | |

| | | | | | | | | | | | | |
|---|---|---|---|---|---|---|---|---|---|---|---|---|
| Photo initiator (C) | C-1 | 5 | | 5 | | 35 | | | 30 | 5 | | |
| (parts by weight) | C-2 | | 10 | 15 | | | 5 | | | | 30 | |
| | C-3 | | | | 30 | | 35 | 45 | 20 | 25 | | 40 |
| Solvent (D) | D-1 | 500 | 1000 | 900 | | 1700 | 3700 | | 3000 | 2000 | | 2000 |
| (parts by weight) | D-2 | | | 800 | 2300 | 1400 | | 4600 | 2000 | | 3000 | 1000 |
| Black pigment (E) | E-1 | 100 | | 240 | | 420 | 360 | 500 | 800 | 350 | | 500 |
| (parts by weight) | E-2 | | 160 | | 350 | | 200 | 200 | | | 420 | |
| Evaluation results | Reliability | ⊚ | ⊚ | ⊚ | ⊚ | ⊚ | ⊚ | ◯ | ◯ | X | X | X |

B-1-1 NK Ester A-BPE-10 (made by Shin-Nakamura Chemical)
B-1-2 SR349 (made by Sartomer Company)
B-1-3 CN301 (made by Sartomer Company)
B-1-4 CN303 (made by Sartomer Company)
B-1-5 CN307 (made by Sartomer Company)
B-1-6 EMA-3000 (made by Nippon Soda Co., Ltd)
B-2-1 trimethylolpropyl triacrylate
B-2-2 dipentaerythritol tetraacrylate
B-2-3 dipentaerythritol hexaacrylate
C-1 1-[9-ethyl-6-(2-methylbenzoyl)-9H-carbazol-3-yl]-ethylketo-1-(O-acetyloxime); OXE-02 (made by Ciba Specialty Chemicals)
C-2 1-[4-(phenylthio)phenyl]-octane-1-2-dione-(O-benzoyloxime); OXE-01 (made by Ciba Specialty Chemicals)
C-3 2-methyl-1-[4-(methylthio) phenyl]-2-morpholino-propane-1-on; IRGACURE 907 (made by Ciba Specialty Chemicals)
D-1 propylene glycol monomethyl ether acetate
D-2 ethyl 3-ethoxypropionate
E-1 MA100 (made by Mitsubishi Chemical)
E-2 MA230 (made by Mitsubishi Chemical)

What is claimed is:

1. A photosensitive resin composition, comprising:
an alkali-soluble resin (A), comprising a resin having an unsaturated group (A-1) which is obtained by polymerizing a mixture, wherein said mixture comprises an epoxy compound having at least two epoxy groups (i) and a compound having at least one carboxyl group and at least one vinyl unsaturated group (ii);
a compound having a vinyl unsaturated group (B), comprising a compound (B-1) having a structure of formula (I): 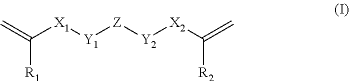
in the formula (I), R₁ and R₂ are independently the same or different, and R₁ and R₂ independently represent a hydrogen atom or a methyl group; X₁ and X₂ are independently the same or different, and X₁ and X₂ independently represent a single bond, an ether group, an oxyalkylene or an ester group; Y₁ and Y₂ are independently the same or different, and Y₁ and Y₂ independently represent a single bond, a methylene group, an ethylene group, an ethyleneoxy group, a propyleneoxy group, a polyethyleneoxy group or a poly propyleneoxy group; and Z is selected from the group consisting of formula (I-1), formula (I-2a), formula (I-2b) or a group formed by a combination of two or more of formula (I-2a) and formula (I-2b): 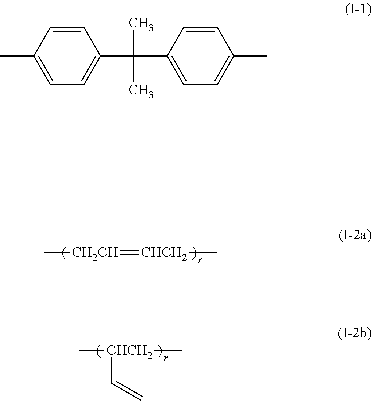
in the formula (I-1), formula (I-2a) and formula (I-2b), the r represents an integer greater than 1;
a photo initiator (C);
a solvent (D); and
a black pigment (E).

2. The photosensitive resin composition of claim 1, wherein the epoxy compound having at least two epoxy group (i) has a structure of formula (II) or formula (III): 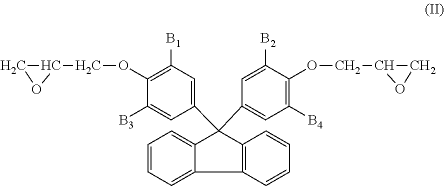
in the formula (II), B₁, B₂, B₃ and B₄ are independently the same or different, and B₁, B₂, B₃ and B₄ independently represent a hydrogen atom, a halogen atom, an alkyl group of 1 to 5 carbons, an alkoxy group of 1 to 5 carbons, an aryl group of 6 to 12 carbons or an aralkyl group of 6 to 12 carbons; 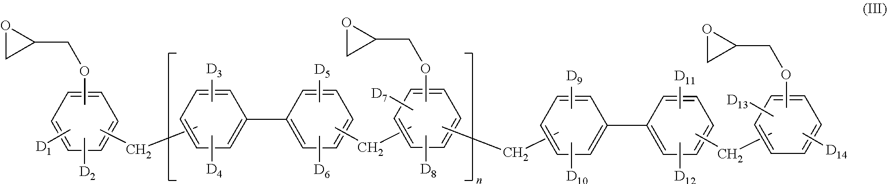
in the formula (III), D₁ to D₁₄ are independently the same or different, and D₁ to D₁₄ independently represent a hydrogen atom, a halogen atom, an alkyl group of 1 to 8 carbons, an aryl group of 6 to 15 carbons, and the n represents an integer from 0 to 10.

3. The photosensitive resin composition of claim 1, based on an amount of the alkali-soluble resin (A) as 100 parts by weight, an amount of the resin having an unsaturated group (A-1) is 30 to 100 parts by weight, an amount of said compound having a vinyl unsaturated group (B) is 10 parts by weight to 100 parts by weight, an amount of said photo initiator (C) is 5 to 50 parts by weight, an amount of said solvent (D) is 500 to 5000 parts by weight, and an amount of said black pigment (E) is 100 to 800 parts by weight.

4. The photosensitive resin composition of claim 1, based on an amount of the alkali-soluble resin (A) as 100 parts by weight, an amount of the compound (B-1) having a structure of formula (I) is 1 part by weight to 15 parts by weight.

5. A black matrix, formed by a photosensitive resin composition of claim 1.

6. A color filter, comprising a black matrix of claim 5.

7. A liquid crystal display device, comprising a color filter of claim 6.
